(19) United States
(12) Patent Application Publication
(10) Pub. No.: US 2018/0308925 A1
(43) Pub. Date: Oct. 25, 2018

(54) HIGH ELECTRON MOBILITY TRANSISTOR

(71) Applicant: Wavetek Microelectronics Corporation, Hsinchu County (TW)

(72) Inventors: Chih-Yen Chen, Tainan City (TW); Hsien-Lung Yang, Taipei City (TW)

(21) Appl. No.: 15/805,156

(22) Filed: Nov. 7, 2017

(30) Foreign Application Priority Data
Apr. 21, 2017 (TW) 106113401

(51) Int. Cl. H01L 29/06; H01L 29/778; H01L 29/10; H01L 29/423

(52) U.S. Cl. CPC H01L 29/063; H01L 29/42368; H01L 29/1054; H01L 29/7786

(57) ABSTRACT

A high electron mobility transistor includes a channel layer, a nitride layer, a source electrode, a drain electrode, a gate electrode, a fluorinated region, and a surface plasma treatment region. The nitride layer is disposed on the channel layer. The source electrode and the drain electrode are disposed above the channel layer. The gate electrode is disposed above the nitride layer and at least partially disposed between the source electrode and the drain electrode in a first direction. The fluorinated region is disposed in the nitride layer. The surface plasma treatment region is at least partially disposed at a top surface of the nitride layer located between the source electrode and the drain electrode. The surface plasma treatment region is separated from the fluorinated region or a fluorine concentration of the surface plasma treatment region is different from a fluorine concentration of the fluorinated region.

### BACKGROUND OF THE INVENTION

### 1. Field of the Invention

The present invention relates to a high electron mobility transistor (HEMT), and more particularly, to an HEMT including a fluorinated region and a surface plasma treatment region.

### 2. Description of the Prior Art

Because of the semiconductor characteristics, III-V semiconductor compounds may be applied in many kinds of integrated circuit devices, such as high power field effect transistors, high frequency transistors, or high electron mobility transistors (HEMTs). In the high electron mobility transistor, two semiconductor materials with different band-gaps are combined and heterojunction is formed at the junction between the semiconductor materials as a channel for carriers. In recent years, gallium nitride (GaN) based materials have been applied in the high power and high frequency products because of the properties of wider band-gap and high saturation velocity. Two-dimensional electron gas (2DEG) may be generated by the polarization property of the GaN-based materials, and the switching velocity may be enhanced because of the higher electron velocity and the higher electron density of the 2DEG.

In the GaN HEMT, a field plate is generally used to deplete the 2DEG under the area covered by the field plate, and the electric field at the off-state may be reduced. The field plate may be used to alter the electric field distribution for enhancing breakdown voltage and suppressing current collapse. However, an additional parasite capacitance may be generated by the field plate, and that will generate negative effect on the operation of the transistor. For example, the switching velocity of the transistor may become slower. In addition, when metal-insulator-semiconductor (MIS) interface is introduced in the gate electrode of the transistor, a parasite normally-on channel may be generated at the surface of the transistor because of the energy band difference and accumulation of defect charge between the insulation layer and the semiconductor layer, and the operation of the normally-off channel under the parasite normally-on channel in the HEMT will be influenced. Therefore, it is an important issue for the related field to solve the above-mentioned problems and improve the electrical performance and the reliability by modifying the structural design and/or the process design.

### SUMMARY OF THE INVENTION

It is one of the objectives of the present invention to provide a high electron mobility transistor (HEMT). A surface plasma treatment region is formed at a top surface of a nitride layer, and the surface plasma treatment region may be separated from a fluorinated region formed in the nitride layer or a fluorine concentration of the surface plasma treatment region is apparently different from a fluorine concentration of the fluorinated region. The surface plasma treatment region may be used to modify the surface energy state and suppress formation of parasitic channel at the surface of the nitride layer, and hysteresis of threshold voltage of the HEMT may be improved accordingly. The purposes of reduced surface field (RESURF), enhancing the breakdown voltage, and eliminating drain induced barrier lowering (DIBL) phenomenon may be achieved by modifying the location and distribution of the surface plasma treatment region.

A high electron mobility transistor is provided in an embodiment of the present invention. The high electron mobility transistor includes a channel layer, a nitride layer, a source electrode, a drain electrode, a gate electrode, a fluorinated region, and a surface plasma treatment region. The nitride layer is disposed on the channel layer. The source electrode and the drain electrode are disposed above the channel layer. The gate electrode is disposed above the nitride layer. The gate electrode is at least partially disposed between the source electrode and the drain electrode in a first direction. The fluorinated region is disposed in the nitride layer. The surface plasma treatment region is at least partially disposed at a top surface of the nitride layer located between the source electrode and the drain electrode. The surface plasma treatment region is separated from the fluorinated region or a fluorine concentration of the surface plasma treatment region is different from a fluorine concentration of the fluorinated region.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic drawing illustrating a high electron mobility transistor (HEMT) according to a first embodiment of the present invention.

FIG. 2 is a schematic drawing illustrating an HEMT according to a second embodiment of the present invention.

FIG. 3 is a schematic drawing illustrating an HEMT according to a third embodiment of the present invention.

FIG. 4 is a schematic drawing illustrating an HEMT according to a fourth embodiment of the present invention.

FIG. 5 is a schematic drawing illustrating an HEMT according to a fifth embodiment of the present invention.

FIG. 6 is a schematic drawing illustrating an HEMT according to a sixth embodiment of the present invention.

FIG. 7 is a schematic drawing illustrating an HEMT according to a seventh embodiment of the present invention.

FIG. 8 is a schematic drawing illustrating an HEMT according to an eighth embodiment of the present invention.

FIG. 9 is a schematic drawing illustrating an HEMT according to a ninth embodiment of the present invention.

FIG. 10 is a schematic drawing illustrating an HEMT according to a tenth embodiment of the present invention.

FIG. 11 is a schematic drawing illustrating an HEMT according to an eleventh embodiment of the present invention.

FIG. 12 is a schematic drawing illustrating an HEMT according to a twelfth embodiment of the present invention.

FIG. 13 is a schematic drawing illustrating an HEMT according to a thirteenth embodiment of the present invention.

FIG. 14 is a schematic drawing illustrating an HEMT according to a fourteenth embodiment of the present invention.

FIG. 15 is a schematic drawing illustrating an HEMT according to a fifteenth embodiment of the present invention.

FIG. 16 is a schematic drawing illustrating an HEMT according to a sixteenth embodiment of the present invention.

FIG. 17 is a schematic drawing illustrating an HEMT according to a seventeenth embodiment of the present invention.

FIG. 18 is a schematic drawing illustrating an HEMT according to an eighteenth embodiment of the present invention.

FIG. 19 is a schematic drawing illustrating an HEMT according to a nineteenth embodiment of the present invention.

FIG. 20 is a schematic drawing illustrating an HEMT according to a twentieth embodiment of the present invention.

### DETAILED DESCRIPTION

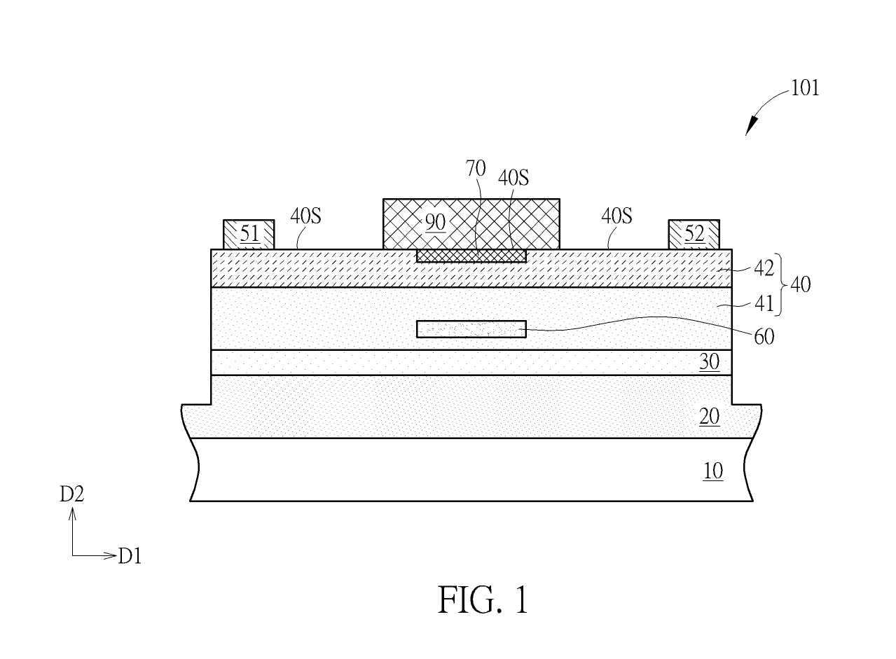

Please refer to FIG. 1. FIG. 1 is a schematic drawing illustrating a high electron mobility transistor (HEMT) according to a first embodiment of the present invention. As shown in FIG. 1, an HEMT 101 is provided in this embodiment. The HEMT 100 includes a channel layer 30, a nitride layer 40, a source electrode 51, a drain electrode 52, a gate electrode 90, a fluorinated region 60, and a surface plasma treatment region 70. The nitride layer 40 is disposed on the channel layer 30. The channel layer 30 may include materials such as gallium nitride (GaN) and/or indium gallium nitride (InGaN), and the nitride layer 40 may include materials such as aluminum gallium nitride (AlGaN), aluminum indium nitride (AlInN), aluminum gallium indium nitride (AlGaInN), aluminum nitride (AlN), and/or silicon nitride. The source electrode 51 and the drain electrode 52 are disposed above the channel layer 30. The gate electrode 90 is disposed above the nitride layer 40, and the gate electrode 90 is at least partially disposed between the source electrode 51 and the drain electrode 52 in a first direction D1. In some embodiments, the source electrode 51 and the drain electrode 52 may be disposed above the nitride layer 40, but not limited thereto. In some embodiments, the source electrode 51 and the drain electrode 52 may also be disposed above the channel 30 without being disposed above the nitride layer 40 according to other considerations. The source electrode 51, the drain electrode 52, and the gate electrode 90 may include conductive metal materials or other suitable conductive materials respectively. The conductive metal materials mentioned above may include gold (Au), tungsten (W), cobalt (Co), nickel (Ni), titanium (Ti), molybdenum (Mo), copper (Cu), aluminum (Al), tantalum (Ta), palladium (Pd), platinum (Pt), a compound of the above-mentioned materials, a stack layer of the above-mentioned materials, or an alloy of the above-mentioned materials, but not limited thereto. The fluorinated region 60 is disposed in the nitride layer 40. The surface plasma treatment region 70 is at least partially disposed at a top surface 40S of the nitride layer 40 located between the source electrode 51 and the drain electrode 52. The surface plasma treatment region 70 is separated from the fluorinated region 60 or a fluorine concentration of the surface plasma treatment region 70 is different from a fluorine concentration of the fluorinated region 60. It is worth noting that the fluorine concentration mentioned in the present invention may include a concentration of fluorine ions or a concentration of fluorine in other state.

In some embodiments, the nitride layer 40 may include a plurality of nitride layers. For example, the nitride layer 40 may include a nitride cap layer 42 and a nitride barrier layer 41 disposed between the nitride cap layer 42 and the channel layer 30, but not limited thereto. In some embodiments, the nitride layer 40 may also be composed of a single material layer for being a barrier layer of the HEMT. When the nitride layer 40 includes the nitride cap layer 42 and the nitride barrier layer 41, the surface plasma treatment region 70 maybe disposed on a top surface (i.e. the top surface 40S) of the nitride cap layer 42 located between the source electrode 51 and the drain electrode 52, and the fluorinated region 60 is disposed in the nitride barrier layer 41. In some embodiments, the nitride cap layer 42 may include materials such as gallium nitride, aluminum nitride, aluminum gallium nitride, and/or silicon nitride, and the nitride barrier layer 41 may include materials such as aluminum gallium nitride, aluminum indium nitride, aluminum gallium indium nitride, and/or aluminum nitride, but not limited thereto. Additionally, the HEMT 101 may further include a buffer layer 20 disposed under the channel layer 30, and the HEMT 101 may be disposed on a substrate 10, but not limited thereto. In some embodiments, the buffer layer 20 may include gallium nitride, aluminum gallium nitride, or other suitable buffer materials. The substrate 10 may include silicon substrate, silicon carbide substrate, gallium nitride substrate, sapphire substrate, or substrate formed by other appropriate materials.

In this embodiment, ions in the surface plasma treatment region 70, such as negative fluorine ions (F⁻), maybe used to alter the energy band at the surface of the nitride layer 40 for suppressing the condition of carrier trapping in the area adjacent to the top surface 40 of the nitride layer 40. Problems such as leakage current and current collapse in the HEMT 101 may be improved accordingly. In addition, the ions in the surface plasma treatment region 70 is not limited to the fluorine ions described above, and other appropriate components (such as chlorine ions or other kinds of negative ions) may also be used to form the surface plasma treatment region 70. In some embodiments, when the ions in the surface plasma treatment region 70 are fluorine ions, a fluorine concentration of an upper part of the surface plasma treatment region 70 may be higher than a fluorine concentration of a lower part of the surface plasma treatment region 70 preferably, and the concentration difference may be formed by controlling the manufacturing method of forming the surface plasma treatment region 70 and/or the process parameters of forming the surface plasma treatment region 70. For example, the concentration difference maybe formed by a two steps method, but not limited thereto. Additionally, in some embodiments, the ion concentration in the surface plasma treatment region 70 may be gradually decreased from a top of the surface plasma treatment region 70 to a bottom of the surface plasma treatment region 70 in a vertical second direction D2, but not limited thereto.

As shown in FIG. 1, in some embodiments, a thickness of the surface plasma treatment region 70 (may also be regarded as a depth of the surface plasma treatment region 70) may be smaller than a thickness of the nitride cap layer 42, but not limited thereto. Additionally, at least a part of the surface plasma treatment region 70 maybe disposed under the gate electrode 90 in the second direction D2, and a length of the surface plasma treatment region 70 in the first direction D1 may be smaller than a length of the gate electrode 90 in the first direction D1, but not limited thereto. Additionally, at least a part of the fluorinated region 60 may be disposed in the nitride barrier layer 41, but not limited thereto. The fluorinated region 60 may include fluorine ions therein, and the fluorine ions may provide static and strong negative charge for effective depleting electrons of the carrier channel. The carrier concentration may become lowered or the channel maybe interrupt, the carrier channel may become normally-off, and the HEMT 101 may be a normally-off transistor, but not limited thereto. The dimension and the depth of the fluorinated region 60 may be controlled by modifying the process parameters of the process for forming the fluorinated region 70, such as an ion implantation or a plasma treatment process. For example, the topmost surface of the fluorinated region 60 may be lower than the topmost surface of the nitride layer 40, and the bottommost surface of the fluorinated region 60 may be higher than the bottommost surface of the nitride layer 40, but not limited thereto. In some embodiments of the present invention, the fluorinated region 60 may contact the bottommost surface of the nitride layer 40. In some embodiments, the fluorine concentration of the surface plasma treatment region 70 may be increased for suppressing the carrier trapping issue in the area adjacent to the top surface 40S of the nitride layer 40 especially when the carrier trapping issue becomes serious, and the fluorine concentration of the surface plasma treatment region 70 maybe higher than the fluorine concentration of the fluorinated region 60 accordingly, but not limited thereto. In some embodiments, when more fluorine ions are required in the fluorinated region 60 for generating the demanded effect of depleting the carriers, the fluorine concentration of the surface plasma treatment region 70 may also be relatively lower than the fluorine concentration of the fluorinated region 60. Additionally, in some embodiments, a fluorine concentration of an upper part of the fluorinated region 60 may be higher than a fluorine concentration of a lower part of the fluorinated region 60, or the fluorine concentration of the fluorinated region 60 may be gradually decreased from a top of the fluorinated region 60 to a bottom of the fluorinated region 60 in the second direction D2, but not limited thereto. It is worth noting that a plasma power or a RF power of the process of forming the fluorinated region 60 may be higher than a plasma power or a RF power of the process of forming the surface plasma treatment region 70 preferably because the fluorinated region 60 is formed in the nitride layer 40 and the surface plasma treatment region 70 is formed at the surface of the nitride layer 40. In addition, the fluorinated region 60 maybe formed before the step of forming the surface plasma treatment region 70, but the present invention is not limited to this. In some embodiments, the fluorinated region 60 may also be formed after the step of forming the surface plasma treatment region 70 according to some considerations.

The following description will detail the different embodiments of the present invention. To simplify the description, identical components in each of the following embodiments are marked with identical symbols. For making it easier to understand the differences between the embodiments, the following description will detail the dissimilarities among different embodiments and the identical features will not be redundantly described.

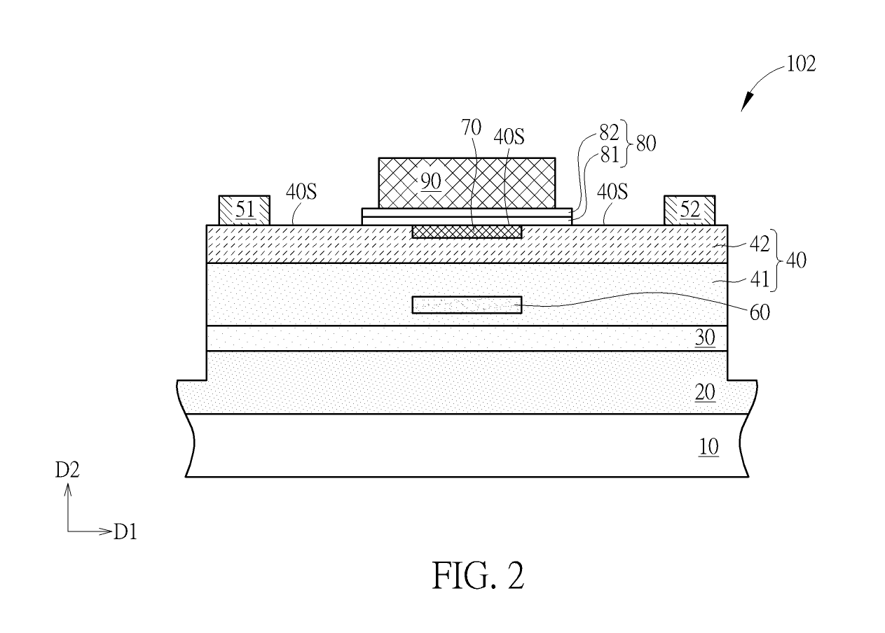

Please refer to FIG. 2. FIG. 2 is a schematic drawing illustrating an HEMT according to a second embodiment of the present invention. As shown in FIG. 2, the difference between an HEMT 102 in this embodiment and the HEMT in the first embodiment mentioned above is that the HEMT 102 may further include agate dielectric layer 80 disposed on the nitride layer 40, and a part of the gate dielectric layer 80 may be disposed between the nitride layer 40 and the gate electrode 90 in the second direction D2. In some embodiments, the gate dielectric layer 80 may extend to cover the source electrode 51, the drain electrode 52, a side surface of the nitride layer 40, and a side surface of the channel layer 30, but not limited thereto. In some embodiments, the gate dielectric layer 80 may be a single layer structure or a structure of stacked multiple material layers. For example, the gate dielectric layer 80 may include a first dielectric layer 81 and a second dielectric layer 82, but not limited thereto. The material of the gate dielectric layer 80 may include aluminum nitride, silicon nitride (such as Si₃N₄), silicon oxide (such as SiO₂), aluminum oxide (such as Al₂O₃), hafnium oxide (such as HfO₂), lanthanum oxide (such as La₂O₃), lutetium oxide (such as Lu₂O₃), lanthanum lutetium oxide (such as LaLuO₃), or other appropriate dielectric materials. In this embodiment, the ions in the surface plasma treatment region 70, such as negative fluorine ions, may be used to alter the energy band at the surface of the nitride layer 40, and the condition of the depletion mode (D-mode) surface channel maybe changed to be a condition of an enhancement mode (E-mode) with higher threshold voltage and that will benefit the stability of the threshold voltage and the enhancement of the drain current.

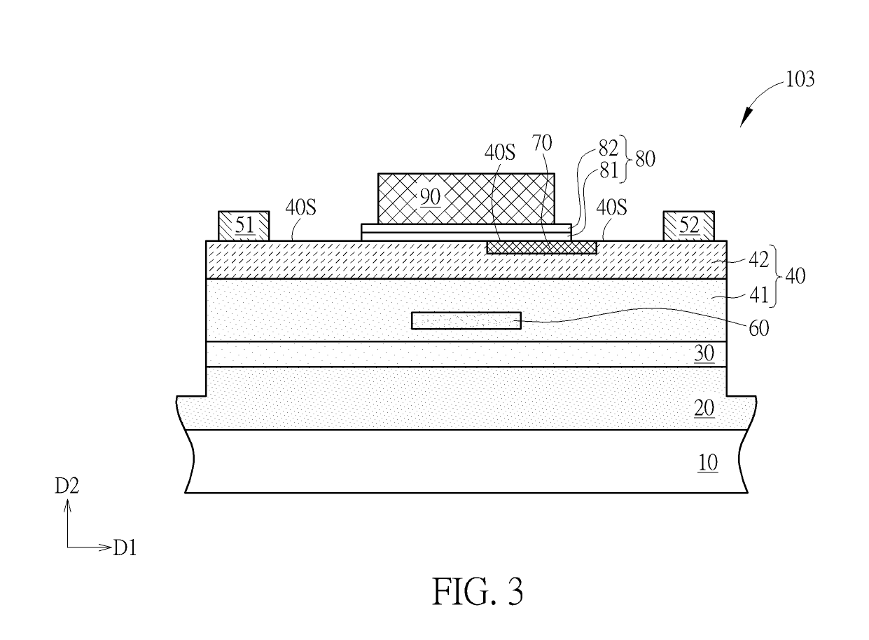

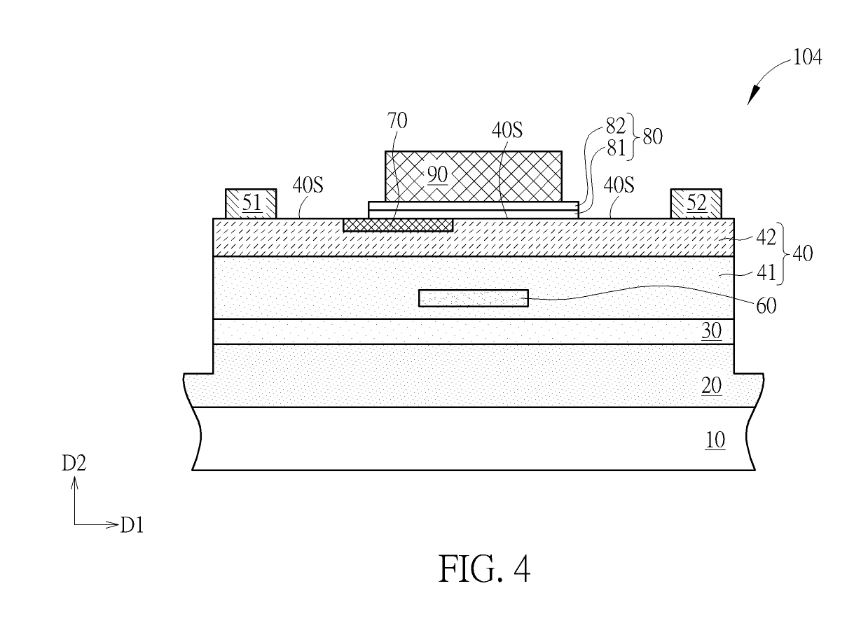

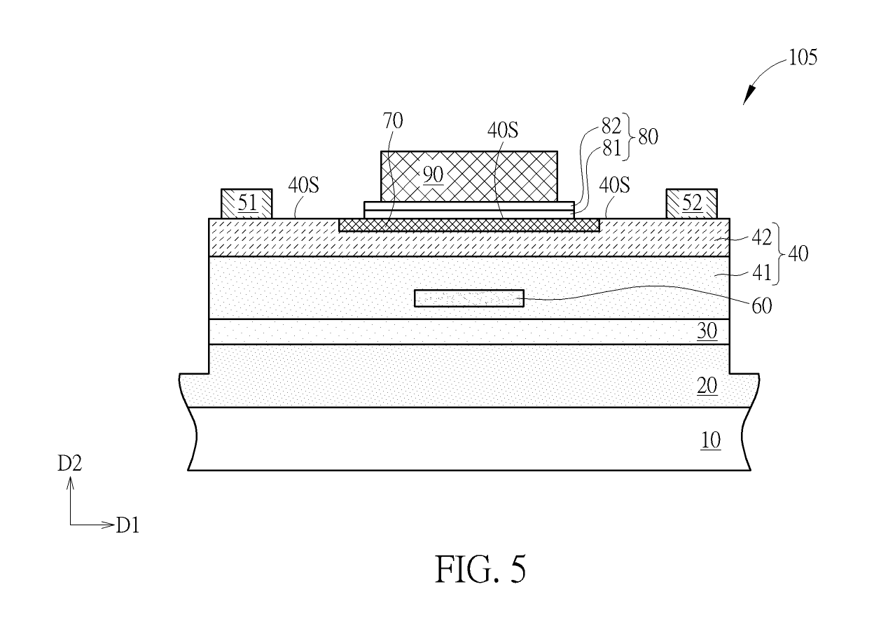

Please refer to FIG. 3, FIG. 4, and FIG. 5. FIG. 3 is a schematic drawing illustrating an HEMT 103 according to a third embodiment of the present invention, FIG. 4 is a schematic drawing illustrating an HEMT 104 according to a fourth embodiment of the present invention, and FIG. 5 is a schematic drawing illustrating an HEMT 105 according to a fifth embodiment of the present invention. In the HEMT of the present invention, the demanded effects of suppressing the current leakage, suppressing the current collapse, improving the hysteresis of the threshold voltage, improving the stability of the threshold voltage, and/or enhancing the drain current may be obtained by modifying the location of the surface plasma treatment region 70. For example, as shown in FIG. 3, in some embodiments, a part of the surface plasma treatment region 70 may be disposed at the top surface 40S of the nitride layer 40 located between the gate electrode 90 and the drain electrode 52. As shown in FIG. 4, in some embodiments, a part of the surface plasma treatment region 70 may be disposed at the top surface 40S of the nitride layer 40 located between the gate electrode 90 and the source electrode 51. As shown in FIG. 5, in some embodiments, the length of the surface plasma treatment region 70 in the first direction D1 may be larger than the length of the gate electrode 90 in the first direction D1, a part of the surface plasma treatment region 70 may be disposed at the top surface 40S of the nitride layer 40 located between the gate electrode 90 and the drain electrode 52, and a part of the surface plasma treatment region 70 maybe disposed at the top surface 40S of the nitride layer 40 located between the gate electrode 90 and the source electrode 51. In some embodiments, the length of the surface plasma treatment region 70 in the first direction D1 may also be substantially equal to the length of the gate electrode 90 in the first direction D1, and the surface plasma treatment region 70 and the gate electrode 90 may overlap each other completely, but not limited thereto. Additionally, in the embodiments shown in FIGS. 3-5 mentioned above, the gate dielectric layer 80 may not be included according to some considerations, and the gate electrode 90 may directly contact the top surface 40 of the nitride layer 40.

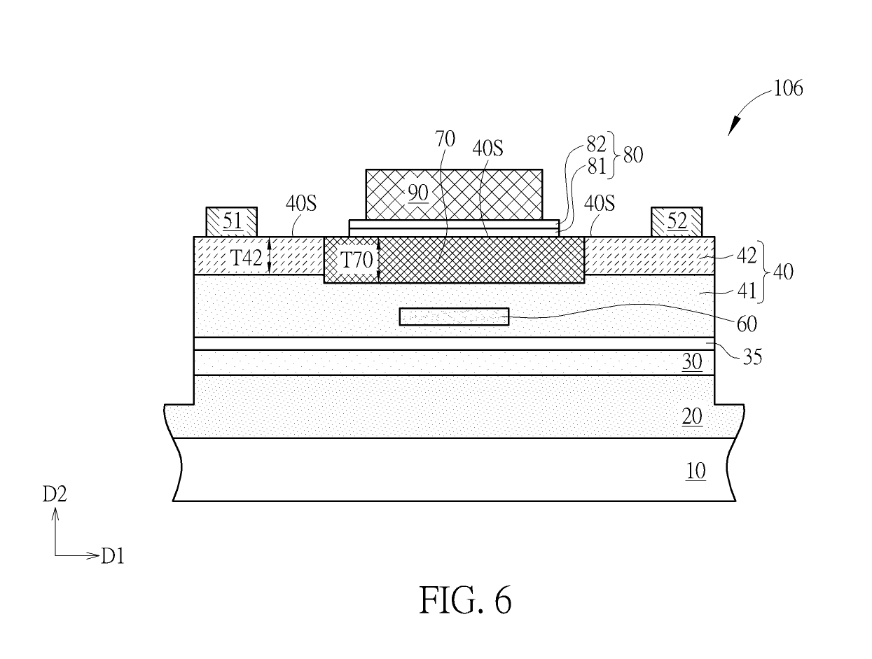

Please refer to FIG. 6 FIG. 6 is a schematic drawing illustrating an HEMT according to a sixth embodiment of the present invention. As shown in FIG. 2, the difference between an HEMT 106 in this embodiment and the HEMT in the fifth embodiment mentioned above is that in the HEMT 106, a thickness of the surface plasma treatment region 70 (such as a second thickness T70 shown in FIG. 6) may be larger than a thickness of the nitride cap layer 42 (such as a first thickness T42 shown in FIG. 6), and a part of the surface plasma treatment region 70 may be disposed in the nitride barrier layer 41. In some embodiments, the second thickness T70 of the surface plasma treatment region 70 may be substantially equal to the first thickness T42 of the nitride cap layer 42, but not limited thereto. Additionally, the HEMT 106 may further include a spacer layer 35 disposed between the nitride barrier layer 41 and the channel layer 30, and the material of the spacer layer 35 may be different from the material of the nitride barrier layer 41 and the material of the channel layer 30. For example, the spacer layer 35 may include materials such as aluminum nitride, aluminum indium nitride, or other suitable III-V compounds. Additionally, the spacer layer 35 in this embodiment may also be applied in other embodiments of the present invention

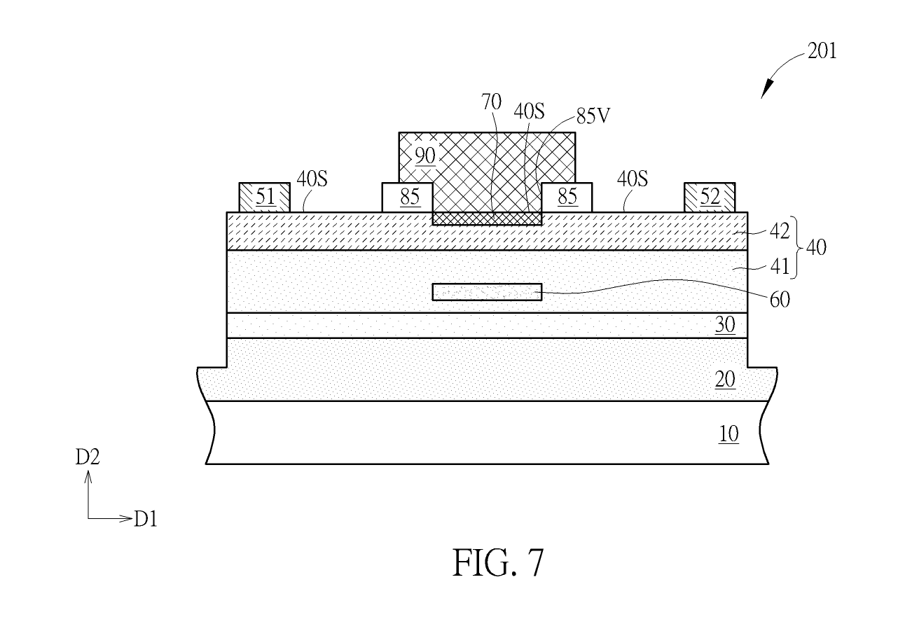

Please refer to FIG. 7. FIG. 7 is a schematic drawing illustrating an HEMT according to a seventh embodiment of the present invention. As shown in FIG. 7, the difference between an HEMT 201 in this embodiment and the HEMT in the first embodiment mentioned above is that the HEMT 201 may further include an insulation layer 85 and a trench 85V. The insulation layer 85 is disposed on the nitride layer 40, and the trench 85V penetrates the insulation layer 85 and exposes part of the nitride layer 40. In some embodiments, the gate electrode 90 may be partly disposed in the trench 85V and partly disposed on a top surface of the insulation layer 85, but not limited thereto. The gate electrode 90 may include a T-shaped structure because of the insulation layer 85, and the gate electrode 90 disposed on the insulation layer 85 may generate field plate effect for further suppressing the current leakage. The material of the insulation layer 85 may include aluminum nitride, silicon nitride, silicon oxide, aluminum oxide, or other suitable insulation materials. In some embodiments, the surface plasma treatment region 70 may be disposed corresponding to the gate electrode 90 in the trench 85V, and the surface plasma treatment region 70 may not overlap the insulation layer 85, but not limited thereto.

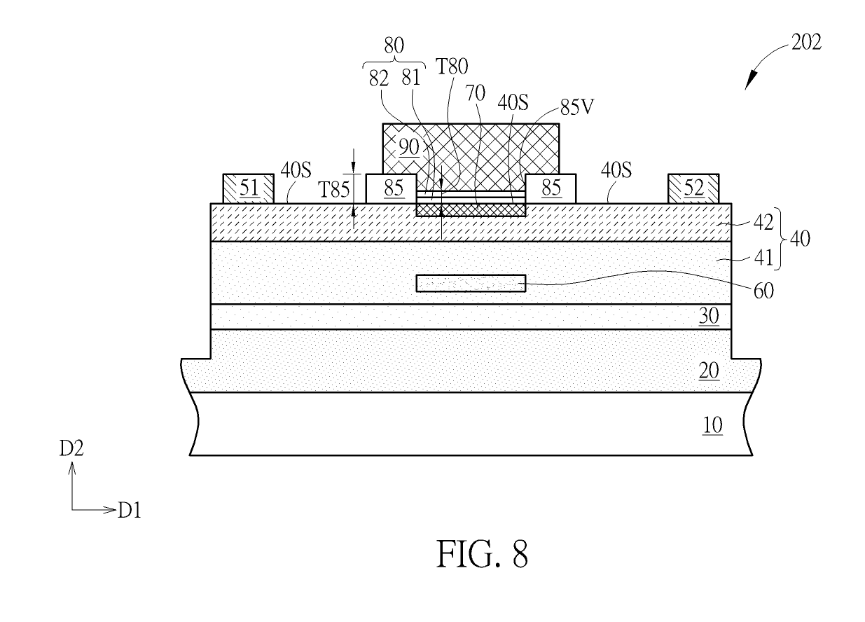

Please refer to FIG. 8. FIG. 8 is a schematic drawing illustrating an HEMT according to an eighth embodiment of the present invention. As shown in FIG. 8, the difference between an HEMT 202 in this embodiment and the HEMT in the seventh embodiment mentioned above is that the HEMT 202 may further include the gate dielectric layer 80, and the gate dielectric layer 80 may be disposed in the trench 85V. A thickness of the gate dielectric layer 80 (such as a third thickness T80 shown in FIG. 8) may be smaller than a thickness of the insulation layer 85 (such as a fourth thickness T85 shown in FIG. 8) preferably, and the gate electrode 90 may still have a T-shaped structure. Additionally, in some embodiments, the gate dielectric layer 80 maybe partly disposed in the trench 85V and partly disposed outside the trench 85V.

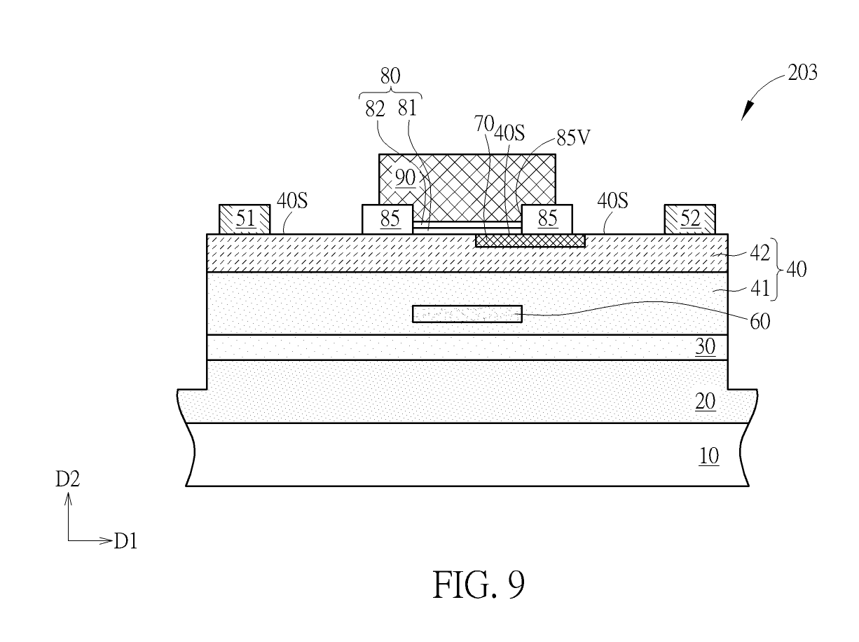

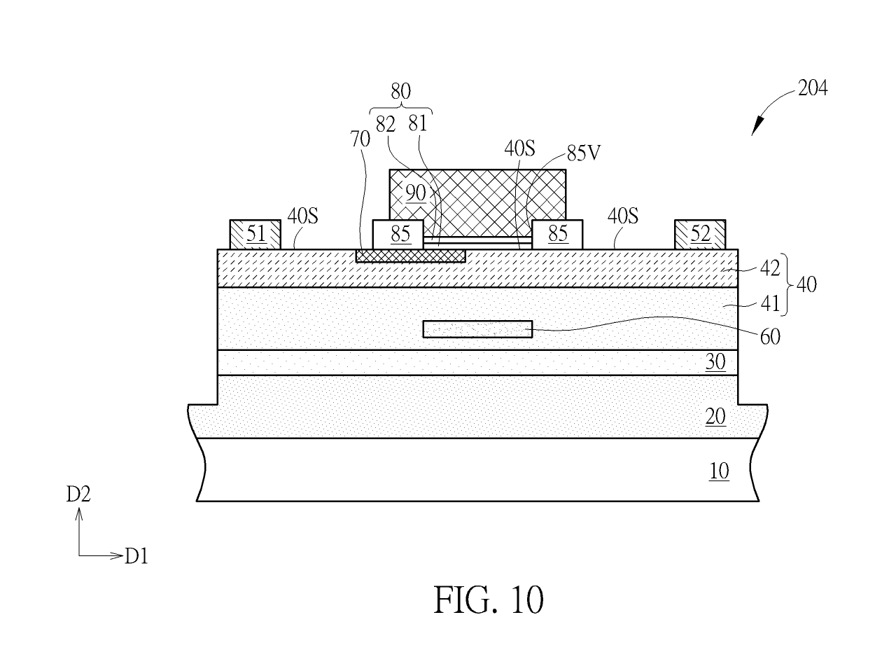

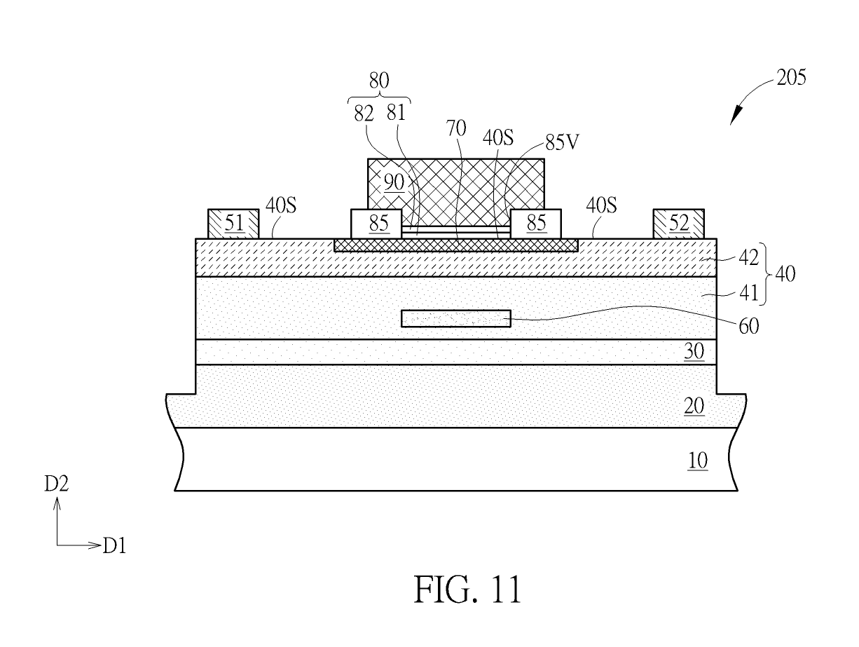

Please refer to FIG. 9, FIG. 10, and FIG. 11. FIG. 9 is a schematic drawing illustrating an HEMT 203 according to a ninth embodiment of the present invention, FIG. 10 is a schematic drawing illustrating an HEMT 204 according to a tenth embodiment of the present invention, and FIG. 11 is a schematic drawing illustrating an HEMT 205 according to an eleventh embodiment of the present invention. In the HEMT of the present invention, the demanded effects of suppressing the current leakage, suppressing the current collapse, improving the hysteresis of the threshold voltage, improving the stability of the threshold voltage, and/or enhancing the drain current may be obtained by modifying the location of the surface plasma treatment region 70. For example, as shown in FIG. 9, in some embodiments, a part of the surface plasma treatment region 70 may be disposed at the top surface 40S of the nitride layer 40 located between the gate electrode 90 and the drain electrode 52, and the surface plasma treatment region 70 may partially overlap the insulation layer 85. As shown in FIG. 10, in some embodiments, a part of the surface plasma treatment region 70 may be disposed at the top surface 40S of the nitride layer 40 located between the gate electrode 90 and the source electrode 51, and the surface plasma treatment region 70 may partially overlap the insulation layer 85. As shown in FIG. 11, in some embodiments, the length of the surface plasma treatment region 70 in the first direction D1 may be larger than the length of the gate electrode 90 in the first direction D1, the surface plasma treatment region 70 may partially overlap the insulation layer 85, and the surface plasma treatment region 70 may be partially disposed at the top surface 40S of the nitride layer 40 located between the gate electrode 90 and the drain electrode 52 and partially disposed at the top surface 40S of the nitride layer 40 located between the gate electrode 90 and the source electrode 51. Additionally, in the embodiments shown in FIGS. 9-11 mentioned above, the gate dielectric layer 80 may not be included according to some considerations, and the gate electrode 90 may directly contact the top surface 40 of the nitride layer 40.

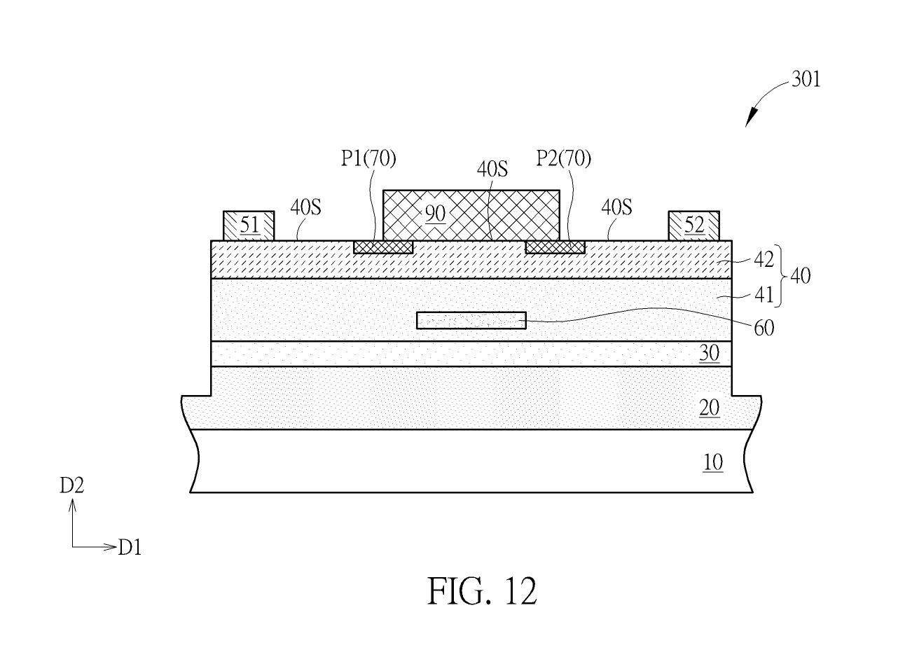

Please refer to FIG. 12. FIG. 12 is a schematic drawing illustrating an HEMT according to a twelfth embodiment of the present invention. As shown in FIG. 12, the difference between an HEMT 301 in this embodiment and the HEMT in the first embodiment mentioned above is that the surface plasma treatment region 70 in the HEMT 301 may include a first part P1 and a second part P2 separated from the first part P1. The first part P1 is partly disposed under the gate electrode 90 and partly disposed at the top surface 40S of the nitride layer 40 located between the source electrode 51 and the gate electrode 90, and the second part is partly disposed under the gate electrode 90 and partly disposed at the top surface 40S of the nitride layer 40 located between the drain electrode 52 and the gate electrode 90. In other words, the first part P1 and the second part P2 of the surface plasma treatment region 70 may be disposed at the top surface 40S of the nitride layer 40 at two opposite sides of the gate electrode 90 in the first direction respectively. A relatively lower gate capacitance may be obtained when the surface plasma treatment region 70 is used to suppress the current collapse and the hysteresis of the threshold voltage because the surface plasma treatment region 70 is divided into the first part P1 and the second part P2 separated from each other.

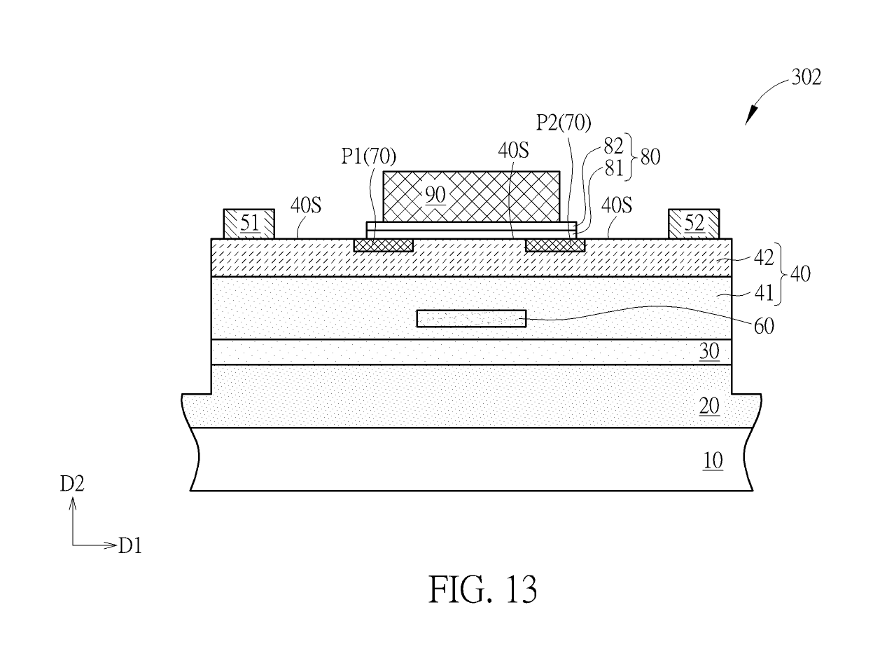

Please refer to FIG. 13. FIG. 13 is a schematic drawing illustrating an HEMT according to a thirteenth embodiment of the present invention. As shown in FIG. 13, the difference between an HEMT 302 in this embodiment and the HEMT in the twelfth embodiment mentioned above is that the HEMT 302 may further include the gate dielectric layer 80 disposed on the nitride layer 40. A part of the gate dielectric layer 80 may be disposed between the gate electrode 90 and the first part P1 of the surface plasma treatment region 70 in the second direction D2, and another part of the gate dielectric layer 80 may be disposed between the gate electrode 90 and the second part P2 of the surface plasma treatment region 70 in the second direction D2.

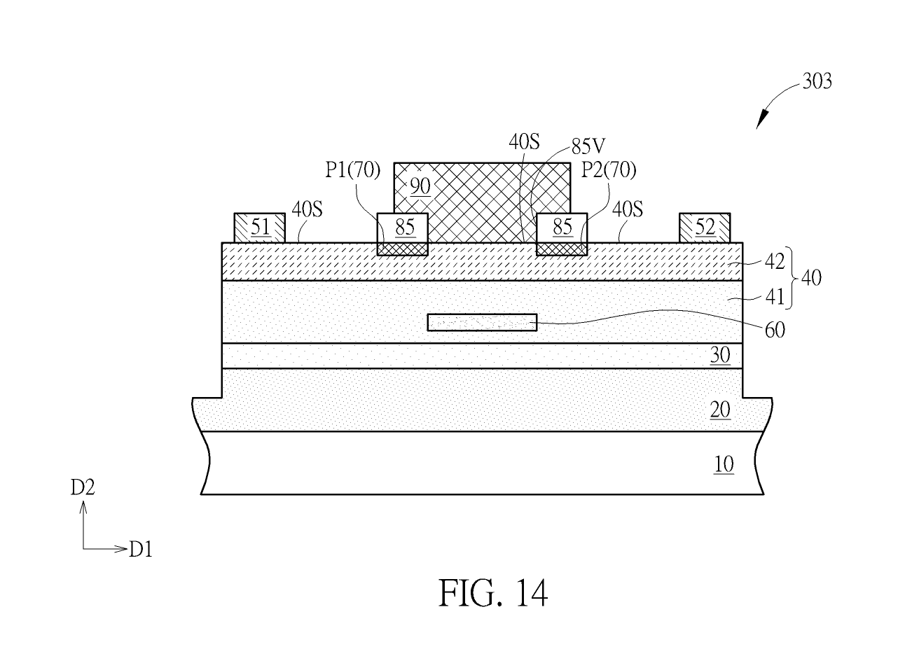

Please refer to FIG. 14. FIG. 14 is a schematic drawing illustrating an HEMT according to a fourteenth embodiment of the present invention. As shown in FIG. 14, the difference between an HEMT 303 in this embodiment and the HEMT in the twelfth embodiment mentioned above is that the HEMT 303 may further include the insulation layer 85 and the trench 85V. The gate electrode 90 may be partly disposed in the trench 85V and partly disposed on the top surface of the insulation layer 85 for forming a T-shaped structure, and the first part P1 and the second part P2 of the surface plasma treatment region 70 may be at least partially disposed under the insulation layer 85. The first part P1 and the second part P2 of the surface plasma treatment region 70 disposed under the insulation layer 85 may be used to reduce a parasite capacitance (Cgs) between the gate electrode 90 and the source electrode 51 and a parasite capacitance (Cgd) between the gate electrode 90 and the drain electrode 52 respectively, and that will benefit the electrical performance of the HEMT 303.

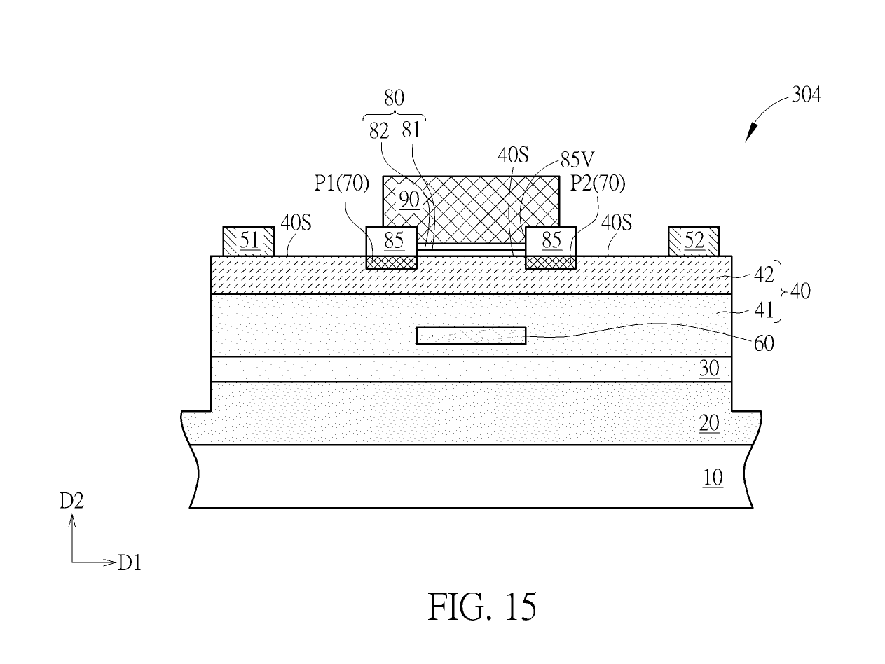

Please refer to FIG. 15. FIG. 15 is a schematic drawing illustrating an HEMT according to a fifteenth embodiment of the present invention. As shown in FIG. 15, the difference between an HEMT 304 in this embodiment and the HEMT in the fourteenth embodiment mentioned above is that the HEMT 304 may further include the gate dielectric layer 80, and the gate dielectric layer 80 may be disposed in the trench 85V. The third thickness T80 of the gate dielectric layer 80 may be smaller than the fourth thickness T85 of the insulation layer 85 preferably, and the gate electrode 90 may still have a T-shaped structure. The first part P1 and the second part P2 of the surface plasma treatment region 70 disposed under the insulation layer 85 may be used to reduce the parasite capacitance between the gate electrode 90 and the source electrode 51 and the parasite capacitance between the gate electrode 90 and the drain electrode 52 respectively.

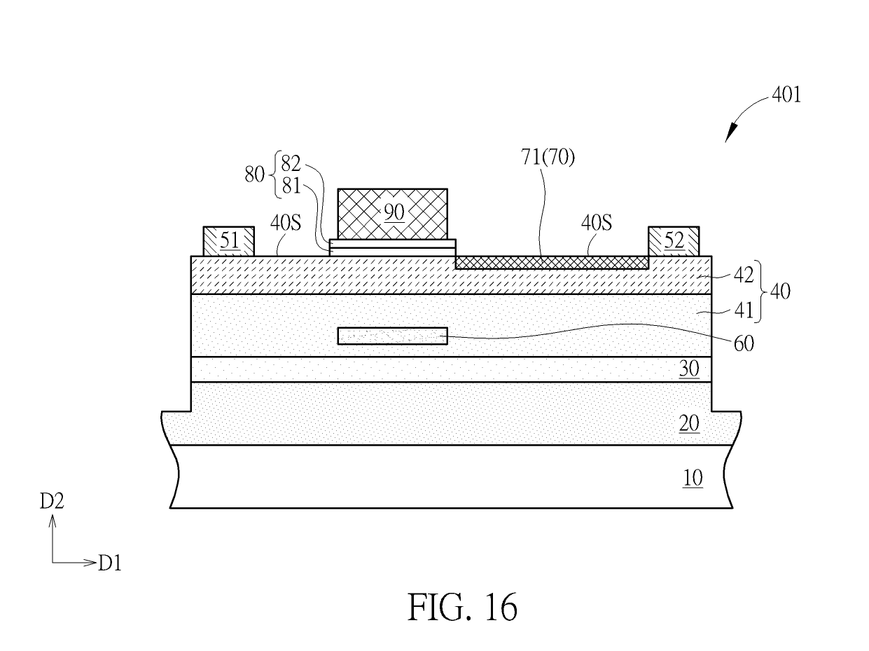

Please refer to FIG. 16. FIG. 16 is a schematic drawing illustrating an HEMT according to a sixteenth embodiment of the present invention. As shown in FIG. 16, the difference between an HEMT 401 in this embodiment and the HEMT in the second embodiment mentioned above is that the surface plasma treatment region 70 in the HEMT 401 may include a first region 71 disposed at the top surface 40S of the nitride layer 40 located between the gate electrode 90 and the drain electrode 52. The first region 71 disposed at the top surface 40S of the nitride layer 40 located between the gate electrode 90 and the drain electrode 52 may be used to provide an effect of reduced surface field (RESURF), and the breakdown voltage of the HEMT 401 may be enhanced accordingly. In addition, a fluorine concentration of the first region 71 may be different from the fluorine concentration of the fluorinated region 60. For example, the ion concentration of the first region 71 of the surface plasma treatment region 70 has been increased to reduce surface electric field when the carrier trapping issue becomes serious at the top surface 40S of the nitride layer 40 located between the gate electrode 90 and the drain electrode 52, and the fluorine concentration of the first region 71 of the surface plasma treatment region 70 may be higher than the fluorine concentration of the fluorinated region 60 accordingly, but not limited thereto. In some embodiments, when more fluorine ions are required in the fluorinated region 60 for generating the demanded effect of depleting the carriers, the fluorine concentration of the first region 71 of the surface plasma treatment region 70 may be relatively lower than the fluorine concentration of the fluorinated region 60. Additionally, in some embodiments, the fluorine concentration of the first region 71 of the surface plasma treatment region 70 may be gradually decreased from a top of the first region 71 to a bottom of the first region 71 in the second direction D2, but not limited thereto. In some embodiments, the fluorine concentration of the first region 71 of the surface plasma treatment region 70 may be gradually increased from a side adjacent to the gate electrode 90 to a side adjacent to the drain electrode 52 for forming a relatively smooth distribution of electric field by the fluorine concentration variation of the first region 71 when the HEMT 401 is a short channel structure, and the purposes of eliminating drain induced barrier lowering (DIBL) phenomenon and realizing the reduced surface field (RESURF) structure may be achieved accordingly, but not limited thereto.

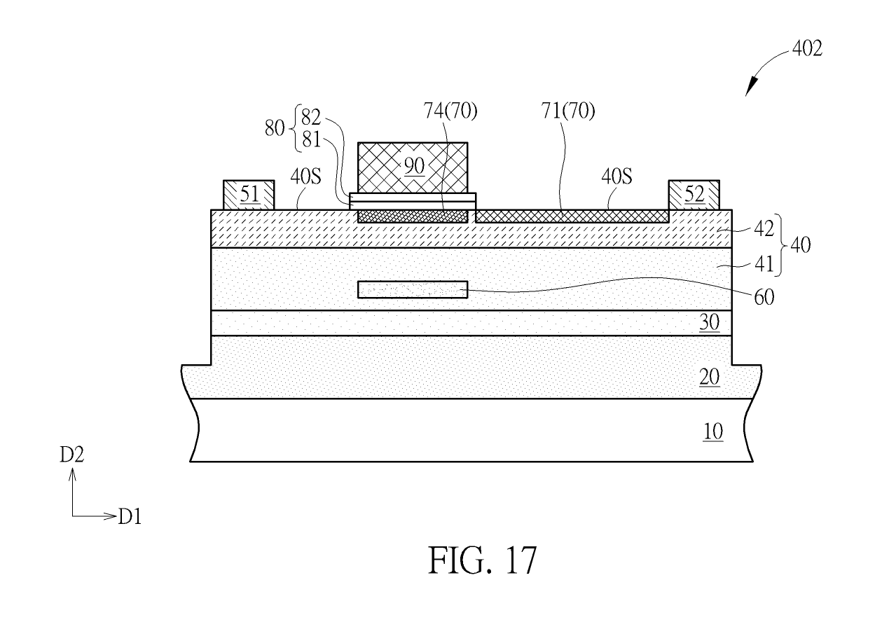

Please refer to FIG. 17. FIG. 17 is a schematic drawing illustrating an HEMT according to a seventeenth embodiment of the present invention. As shown in FIG. 17, the difference between an HEMT 402 in this embodiment and the HEMT in the sixteenth embodiment mentioned above is that the surface plasma treatment region 70 in the HEMT 402 may further include a fourth region 74 disposed at the top surface 40S of the nitride layer 40 under the gate electrode 90, and a fluorine concentration of the fourth region 74 may be different from the fluorine concentration of the fluorinated region 60. The fourth region 74 of the surface plasma treatment region 70 may be used to eliminate the D-mode channel at the surface of the transistor and that will benefit the stability of the threshold voltage and the enhancement of the drain current.

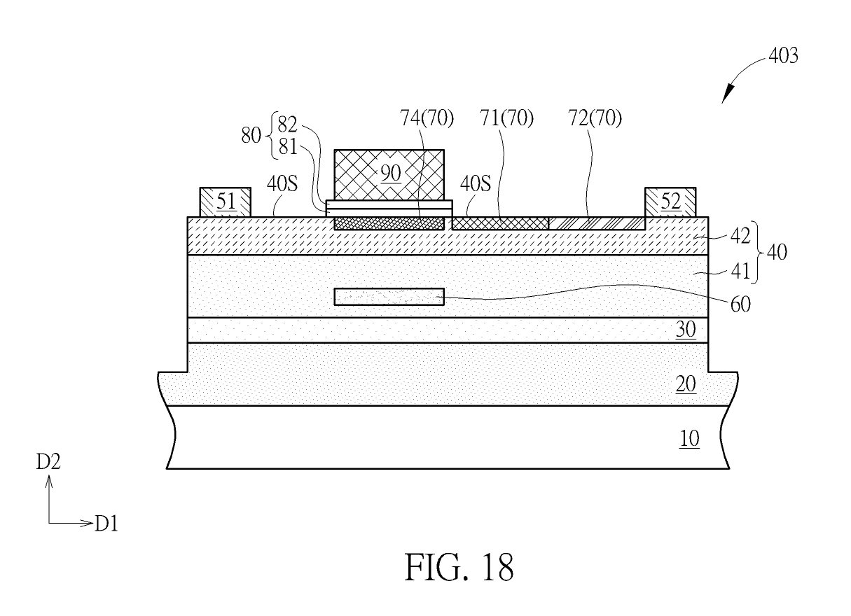

Please refer to FIG. 18. FIG. 18 is a schematic drawing illustrating an HEMT according to an eighteenth embodiment of the present invention. As shown in FIG. 18, the difference between an HEMT 403 in this embodiment and the HEMT in the seventeenth embodiment mentioned above is that the surface plasma treatment region 70 in the HEMT 403 may further include a second region 72 disposed at the top surface 40S of the nitride layer 40 and disposed between the first region 71 and the drain electrode 52. Additionally, a fluorine concentration of the second region 72 which is relatively closer to the drain electrode 52 is higher than the fluorine concentration of the first region 71 which is relatively closer to the gate electrode 90 for eliminating DIBL phenomenon and optimizing the RESURF structure, but not limited thereto.

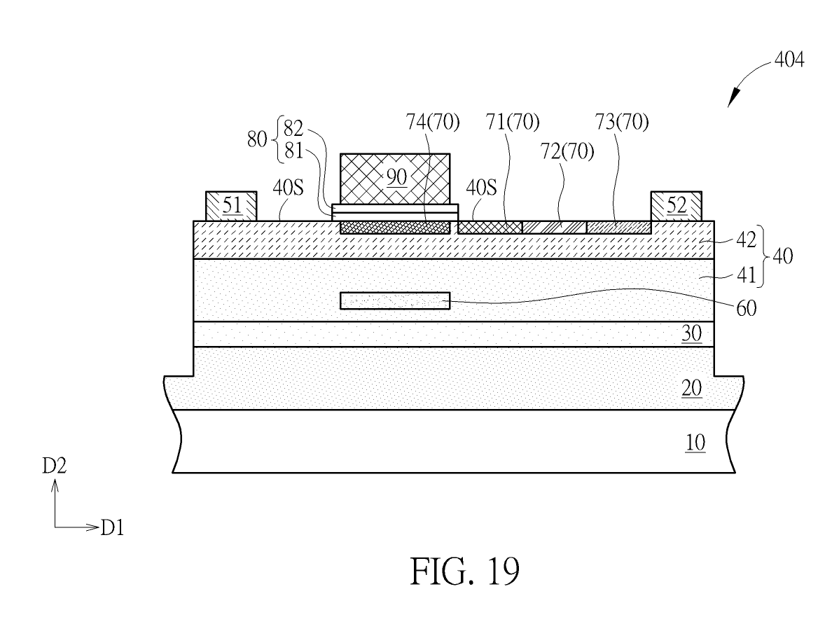

Please refer to FIG. 19. FIG. 19 is a schematic drawing illustrating an HEMT according to a nineteenth embodiment of the present invention. As shown in FIG. 19, the difference between an HEMT 404 in this embodiment and the HEMT in the eighteenth embodiment mentioned above is that the surface plasma treatment region 70 in the HEMT 404 may further include a third region 73 disposed at the top surface 40S of the nitride layer 40 and disposed between the second region 72 and the drain electrode 52. A fluorine concentration of the third region 73 which is relatively closer to the drain electrode 52 is higher than the fluorine concentration of the first region 71 and the fluorine concentration of the second region 72 for eliminating DIBL phenomenon and optimizing the RESURF structure, but not limited thereto.

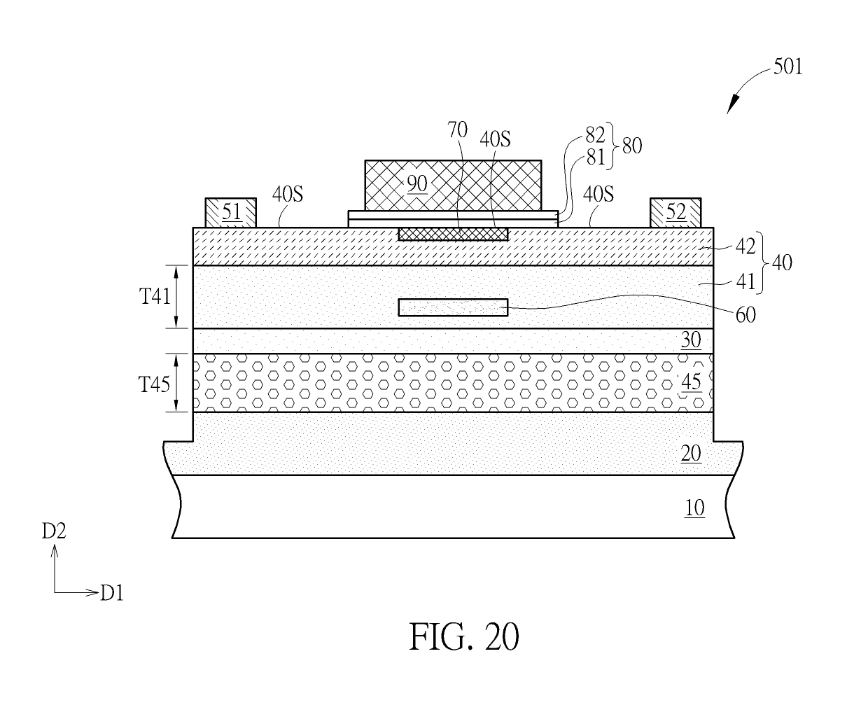

Please refer to FIG. 20. FIG. 20 is a schematic drawing illustrating an HEMT according to a twentieth embodiment of the present invention. As shown in FIG. 20, the difference between an HEMT 501 in this embodiment and the HEMT in the second embodiment mentioned above is that the HEMT 501 may further include an anti-polarization layer 45 disposed between the buffer layer 20 and the channel layer 30. In some embodiments, the HEMT 501 may be a Ga-polarity GaN HEMT, and the nitride barrier layer 41 disposed above the channel layer 30 may be used to sustain a two-dimensional electron gas (2DEG) formed in the channel layer 30 and/or formed between the channel layer 30 and the nitride barrier layer 41. The net polarization charge between the nitride barrier layer 41 and the channel layer 30 is positive polarity, and that will create a potential well at the interface. The ionized carriers swept by the polarization field distribution into the potential well form the two-dimensional electron gas. The anti-polarization layer 45 having a thickness comparable to that of the nitride barrier layer 41 or having a polarization field comparable to that of the nitride barrier layer 41 is disposed under the channel layer 30 for altering the potential distribution of energy band diagram under the channel layer 30, and more ionized carriers may be provided by the channel layer 30 to the potential well between the nitride barrier layer 41 and the channel layer 30. The polarized charge on the surface of the HEMT 501 may be reduced accordingly, and the purposes of reduced surface field (RESURF) and suppressing the current collapse issue maybe achieved. In some embodiments, considering feasible process variation control, a thickness of the anti-polarization layer 45 (such as a sixth thickness T45 shown in FIG. 20) may be substantially equal to a thickness of the nitride barrier layer 41 (such as a fifth thickness T41 shown in FIG. 20) with a tolerance of ±25%. In other words, the sixth thickness T45 of the anti-polarization layer 45 is equal to the fifth thickness T41 of the nitride barrier layer 41 preferably, but the sixth thickness T45 of the anti-polarization layer 45 may range from 0.75 times the fifth thickness T41 of the nitride barrier layer 41 to 1.25 times the fifth thickness T41 of the nitride barrier layer 41. The anti-polarization layer 45 within this thickness range can still provide specific effect. In some embodiments, the tolerance described above may be further reduced to be ±10% or even ±5% for ensuring the uniformity of electrical properties between a plurality of the HEMTs 501, but not limited thereto.

Additionally, in some embodiments, the material of the anti-polarization layer 45 may be the same as the material of the nitride barrier layer 41 preferably. In other words, the anti-polarization layer 45 may include materials such as aluminum gallium nitride, aluminum indium nitride, aluminum gallium indium nitride, and/or aluminum nitride, but not limited thereto. In some embodiments, the anti-polarization layer 45 and the nitride barrier layer 41 may include a III-V compound respectively, and the III-V compound may include a first group III element and a second group III element. For example, in aluminum gallium nitride, the first group III element may be aluminum and the second group III element may be gallium, but not limited thereto. Anatomic ratio of each of the group III elements in the anti-polarization layer 45 is equal to that in the nitride barrier layer 41 preferably. However, considering the feasible process variation control, anatomic ratio of the first group III element in the anti-polarization layer 45 may be substantially equal to anatomic ratio of the first group III element in the nitride barrier layer 41 with a tolerance of ±25%, and the anti-polarization layer 45 within this atomic ratio range can still provide specific effect. For example, when the anti-polarization layer 45 and the nitride barrier layer 41 are both aluminum gallium nitride, the material composition of the nitride barrier layer 41 may be shown as AlₓGa₁₋ₓN, the material composition of the anti-polarization layer 45 may be shown as Al_{y1}Ga_{1-y1}N, and Y1 may range from 0.75× to 1.25×, but not limited thereto. Additionally, in some embodiments, the atomic ratio of the first group III element (such as aluminum) in the anti-polarization layer 45 may be gradually decreased from the top of the anti-polarization layer 45 to the bottom of the anti-polarization layer 45. In other words, the portion of the anti-polarization layer 45 connected to the buffer layer 20 may include less aluminum or include no aluminum for avoiding problems such as parasite 2DEG formed additionally and/or a bending issue of the substrate 10 during manufacturing processes because of the polarization difference between the buffer layer 20 and the anti-polarization layer 45, but not limited thereto. In some embodiments, the anti-polarization layer 45 may also be doped with carbon or iron to increase the interface resistance for suppressing current leakage paths formed by the parasite 2DEG, but not limited thereto. Additionally, the anti-polarization layer 45 in this embodiment may also be applied in other embodiments of the present invention.

To summarize the above descriptions, in the HEMT of the present invention, the surface plasma treatment region separated from the fluorinated region or the surface plasma treatment region has the fluorine concentration different from that of the fluorinated region is formed at the top surface of the nitride layer. The fluorinated region may be used to deplete the carrier channel, and the carrier channel may become normally-off accordingly. The surface plasma treatment region may be used to modify the surface energy band and eliminate the depletion mode channel and that will benefit the stability of the threshold voltage, the hysteresis of the threshold voltage, and the enhancement of the drain current. The effects of reduced surface field (RESURF), enhancing the breakdown voltage, and eliminating drain induced barrier lowering (DIBL) phenomenon may be obtained by modifying the distribution of the surface plasma treatment region.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A high electron mobility transistor (HEMT), comprising:
a channel layer;
a nitride layer disposed on the channel layer;
a source electrode and a drain electrode disposed above the channel layer;
a gate electrode disposed above the nitride layer, wherein the gate electrode is at least partially disposed between the source electrode and the drain electrode in a first direction;
a fluorinated region disposed in the nitride layer; and
a surface plasma treatment region at least partially disposed at a top surface of the nitride layer located between the source electrode and the drain electrode, wherein the surface plasma treatment region is separated from the fluorinated region or a fluorine concentration of the surface plasma treatment region is different from a fluorine concentration of the fluorinated region.

2. The HEMT of claim 1, wherein a length of the surface plasma treatment region in the first direction is smaller than a length of the gate electrode in the first direction.

3. The HEMT of claim 1, wherein a length of the surface plasma treatment region in the first direction is larger than a length of the gate electrode in the first direction.

4. The HEMT of claim 1, wherein at least a part of the surface plasma treatment region is disposed under the gate electrode.

5. The HEMT of claim 1, wherein at least a part of the surface plasma treatment region is disposed at the top surface of the nitride layer disposed between the source electrode and the gate electrode.

6. The HEMT of claim 1, wherein at least a part of the surface plasma treatment region is disposed at the top surface of the nitride layer disposed between the drain electrode and the gate electrode.

7. The HEMT of claim 1, wherein the nitride layer comprises:
a nitride cap layer; and
a nitride barrier layer disposed between the nitride cap layer and the channel layer, wherein the surface plasma treatment region is disposed at a top surface of the nitride cap layer located between the source electrode and the drain electrode, and the fluorinated region is disposed in the nitride barrier layer.

8. The HEMT of claim 7, wherein a thickness of the surface plasma treatment region is larger than a thickness of the nitride cap layer, and the surface plasma treatment region is partially disposed in the nitride barrier layer.

9. The HEMT of claim 7, further comprising:
a buffer layer disposed under the channel layer; and
an anti-polarization layer disposed between the buffer layer and the channel layer, wherein a thickness of the anti-polarization layer is substantially equal to a thickness of the nitride barrier layer with a tolerance of ±25%.

10. The HEMT of claim 9, wherein the anti-polarization layer and the nitride barrier layer comprise a III-V compound including a first group III element and a second group III element respectively, and an atomic ratio of the first group III element in the anti-polarization layer is substantially equal to an atomic ratio of the first group III element in the nitride barrier layer with a tolerance of ±25%.

11. The HEMT of claim 1, further comprising:
an insulation layer disposed on the nitride layer; and
a trench penetrating the insulation layer and exposing a part of the nitride layer, wherein the gate electrode is partly disposed in the trench and partly disposed on a top surface of the insulation layer.

12. The HEMT of claim 11, further comprising:
a gate dielectric layer disposed between the gate electrode and the nitride layer, wherein the gate dielectric layer is at least partially disposed in the trench.

13. The HEMT of claim 1, wherein the surface plasma treatment region comprises:
a first part partly disposed under the gate electrode and partly disposed at the top surface of the nitride layer located between the source electrode and the gate electrode; and
a second part partly disposed under the gate electrode and partly disposed at the top surface of the nitride layer located between the drain electrode and the gate electrode, wherein the first part is separated from the second part.

14. The HEMT of claim 13, further comprising:
an insulation layer disposed on the nitride layer; and
a trench penetrating the insulation layer and exposing a part of the nitride layer, wherein the gate electrode is partly disposed in the trench and partly disposed on a top surface of the insulation layer, and the first part and the second part of the surface plasma treatment region are at least partially disposed under the insulation layer.

15. The HEMT of claim 1, wherein a fluorine concentration of an upper part of the surface plasma treatment region is higher than a fluorine concentration of a lower part of the surface plasma treatment region.

16. The HEMT of claim 1, wherein the surface plasma treatment region comprises:
a first region disposed at the top surface of the nitride layer located between the gate electrode and the drain electrode, wherein a fluorine concentration of the first region is different from a fluorine concentration of the fluorinated region.

17. The HEMT of claim 16, wherein the fluorine concentration of the first region is higher than the fluorine concentration of the fluorinated region.

18. The HEMT of claim 16, wherein the fluorine concentration of the first region is lower than the fluorine concentration of the fluorinated region.

19. The HEMT of claim 16, wherein the surface plasma treatment region further comprises:
a second region disposed at the top surface of the nitride layer and disposed between the first region and the drain electrode, wherein a fluorine concentration of the second region is higher than the fluorine concentration of the first region.

20. The HEMT of claim 19, wherein the surface plasma treatment region further comprises:
a third region disposed at the top surface of the nitride layer and disposed between the second region and the drain electrode, wherein a fluorine concentration of the third region is higher than the fluorine concentration of the second region.

21. The HEMT of claim 16, wherein the surface plasma treatment region further comprises:
a fourth region disposed at the top surface of the nitride layer under the gate electrode, wherein a fluorine concentration of the fourth region is different from the fluorine concentration of the fluorinated region.

22. The HEMT of claim 1, wherein the fluorine concentration of the surface plasma treatment region is higher than the fluorine concentration of the fluorinated region.

23. The HEMT of claim 1, wherein the fluorine concentration of the surface plasma treatment region is lower than the fluorine concentration of the fluorinated region.
